(19) United States
(12) Patent Application Publication
(10) Pub. No.: US 2026/0251746 A1
(43) Pub. Date: Aug. 27, 2026

(54) ASCERTAINING PULSES BY TAKING INTO CONSIDERATION INHOMOGENEITY REGIONS

(71) Applicant: Siemens Healthineers AG, Forchheim (DE)

(72) Inventors: David Grodzki, Erlangen (DE); Christian Eisen, Nürnberg (DE)

(21) Appl. No.: 19/542,896

(22) Filed: Feb. 18, 2026

(30) Foreign Application Priority Data
Feb. 27, 2025 (DE) 10 2025 107 515.8

(51) Int. Cl. G01R 33/565

(52) U.S. Cl. CPC G01R 33/56563; G01R 33/56572

(57) ABSTRACT

The disclosure relates to a method for ascertaining at least one pulse of a magnetic resonance sequence for a magnetic resonance measurement, a magnetic resonance apparatus, and a computer program product. According to the method, at least one magnetic field map and at least one homogeneity condition are provided. At least one pulse, which has been optimized based on the at least one magnetic field map, is ascertained by taking into consideration the at least one inhomogeneity region.

### TECHNICAL FIELD

The present patent document claims the benefit of German Patent Application No. 10 2025 107 515.8, filed Feb. 27, 2025, which is hereby incorporated by reference in its entirety.

The disclosure relates to a method for ascertaining at least one pulse of a magnetic resonance sequence for a magnetic resonance measurement, a magnetic resonance apparatus, and a computer program product.

### BACKGROUND

In medical engineering, imaging is characterized by high soft tissue contrast by magnetic resonance (MR), also referred to as magnetic resonance tomography (MRT) or magnetic resonance imaging (MRI). Here, a patient is positioned in an examination region of a magnetic resonance apparatus, in which a main magnet of the magnetic resonance apparatus generates a main magnetic field (also referred to as B0 field). During a magnetic resonance measurement, according to a magnetic resonance sequence, radiofrequency (RF) transmit pulses are irradiated into the examination region in order to generate an alternating magnetic field (also referred to as B1 field) and gradient pulses are irradiated into the examination region in order to generate a magnetic field gradient which is overlaid onto the main magnetic field, thus exciting nuclear spins in the examination object. This triggers spatially encoded echo signals in the examination object, which may also be referred to as magnetic resonance signals. The magnetic resonance signals may be used for the reconstruction of magnetic resonance images.

In addition to “static” pulses, in which, e.g., only the frequency, duration, and phase are adapted, so-called dynamic pulses are also known. These are characterized in that they are calculated on a situation-dependent basis, for example, as a function of a prevailing B0 and/or B1 field distribution. Such pulses are used in the ultra-high field range (e.g., >3T), in which the B1 fields may be very inhomogeneous, where they may be optimized and applied with more than one transmission channel. However, even in the case of magnetic resonance apparatuses with a lower field strength (e.g., ≤3T) and/or with only one transmission channel, there are application targets of dynamic pulses, such as dynamic fat saturation (dFX). In the case of dFX, the “static” fat saturation pulse is replaced with a dynamic pulse, which is configured to the prevailing B0 and/or B1 field distribution, in order to achieve a homogeneous fat saturation precisely in regions of strong non-linear magnetic field fluctuations.

### SUMMARY AND DESCRIPTION

The object of the present disclosure may be considered to be improving the ascertainment of pulses, (e.g., dynamic pulses), of a magnetic resonance sequence.

The scope of the present disclosure is defined solely by the appended claims and is not affected to any degree by the statements within this summary. The present embodiments may obviate one or more of the drawbacks or limitations in the related art.

Accordingly, a computer-implemented method for ascertaining at least one pulse, (e.g., at least one dynamic pulse), of a magnetic resonance sequence for a magnetic resonance measurement is proposed. Here, at least one magnetic field map and at least one homogeneity condition are provided. At least one pulse, (e.g., at least one dynamic pulse), which has been optimized on the basis of the at least one magnetic field map, is ascertained by taking into consideration the at least one inhomogeneity region. Advantageously, the magnetic resonance measurement is carried out using the at least one pulse, e.g., at least one dynamic pulse.

A magnetic resonance sequence may include a series of pulses, in particular RF pulses and/or gradient pulses. The MR sequence may be used for the excitation of an image volume to be measured, for signal generation, and/or for spatial encoding. A range of different types of magnetic resonance sequences are known, such as spin echo sequences or gradient echo sequences, wherein the application of the proposed method is not limited to a particular sequence type. The magnetic resonance sequence may include several pulses that have been ascertained by the proposed method.

An RF transmit pulse may be regarded as a dynamic pulse in which the phase and/or amplitude changes during the temporal course of the pulse. During the course thereof, it may be possible to sample a gradient trajectory, e.g., a predetermined gradient trajectory, by a gradient coil unit of the magnetic resonance apparatus. In particular, the sampling of the gradient trajectory takes place temporally with the variation of the phase and/or amplitude of the RF transmit pulse. The totality of RF transmit pulse and gradient trajectory may also be considered as the dynamic pulse. The RF transmit pulse would then be a part of the dynamic pulse.

In particular, the dynamic pulse (in contrast to “static” pulses) has an arbitrary pulse form. In particular, the pulse form of the at least one dynamic pulse is ascertained as a function of the at least one magnetic field map.

An embodiment of the method provides that the ascertainment of the at least one dynamic pulse includes an optimization of a homogeneity of a flip angle distribution that may be generated, in particular is to be generated, by the dynamic pulse. The optimization may take place based on the at least one magnetic field map. The dynamic pulse, in particular the pulse form thereof, may be optimized based on the at least one magnetic field map, in particular with regard to a maximum homogeneity of the flip angle distribution. Advantageously, any arbitrary pulse form is available for optimizing the flip angle distribution.

A pulse form may be the profile and/or the shape of a pulse. A pulse form may be described by an envelope curve of the pulse, in particular in the base band. The pulse form may be independent of an absolute height, in particular amplitude, and/or an absolute width, in particular length, of the pulse.

A pulse form of a pulse may be described by a temporal course of the pulse, in particular an instantaneous value and/or a deflection of the pulse, for example, expressed as a pulse profile S(t), wherein the pulse profile S(t) may be described by a complex-value function and t represents the time.

The at least one pulse form and/or amplitude and/or phase of the RF transmit pulse or of a partial pulse may correspond to a form and/or amplitude and/or phase of a voltage pulse that is applied to the respective transmission coil, and/or of a current pulse that flows through the transmission coil.

The at least one pulse form and/or amplitude and/or phase of the gradient pulse may correspond to a form and/or amplitude and/or phase of a voltage pulse that is applied to the gradient coil unit, and/or of a current pulse that flows through the gradient coil unit.

By way of a dynamic pulse, it is advantageously possible to control the B1 field thus generated more precisely. In particular, a pTx pulse may be used to even out magnetic field inhomogeneities, which may be especially advantageous at higher Tesla field strengths of the main magnetic field. A dynamic parallel transmission may be advantageous precisely in the case of high field strengths, because the B1 effects occurring there may be so short-wave that they would be visible within a magnetic resonance image. Even in the case of lower field strengths, however, the application of a dynamic pulse as described above, such as for fat saturation, may be advantageous. The dynamic pulse may be a fat saturation pulse.

An embodiment of the method provides that the dynamic pulse is a pTx pulse. Here, “pTx” stands for “parallel transmission.” A pTx pulse may include several partial pulses, which are transmitted in parallel, in particular simultaneously, in each case by a transmission coil of a radiofrequency antenna unit of the magnetic resonance apparatus. A transmission channel may in turn be assigned to each transmission coil. Therein, the partial pulses may differ, e.g., in their pulse form and/or amplitude and/or phase. Furthermore, the partial pulses may have a temporal delay relative to one another. For example, an emittable RF transmit pulse is composed of a plurality of partial pulses, which differ from one another and may each be transmitted by a transmission coil of a multichannel transmission coil arrangement of the radiofrequency antenna unit. In certain examples, at least some of the plurality of partial pulses, in particular all the partial pulses, are dynamic pulses.

During a transmission of a pTx pulse, it is advantageously possible to achieve a predetermined spatial distribution of the excitation as an additional degree of freedom by interference of the signals of the plurality of transmission channels via a plurality of transmission coils of the radiofrequency antenna unit, which is adjusted during the ascertainment of the pTx pulse, for example by variation of the phase and amplitude.

In particular, a computing unit may include one or several processors and/or one or several memory modules configured to carry out the method.

In certain examples, a check is carried out to determine whether the at least one homogeneity condition is not fulfilled in at least one region of the at least one magnetic field map, which region is referred to in the following as the inhomogeneity region and, if this is the case, at least one, at least dynamic, pulse of the magnetic resonance sequence, which pulse has been optimized on the basis of the at least one magnetic field map, is ascertained by taking into consideration the at least one inhomogeneity region. If there is no inhomogeneity region, the ascertainment of the at least one pulse, e.g., at least one dynamic pulse, may take place in a conventional manner.

If the inhomogeneities are too great, for example, in the case of particularly strong B0 field disturbances in the vicinity of metal and/or at a greater distance from the isocenter, it may not be possible to carry out a satisfactory pulse calculation, as a result of which the measurement result may have artifacts. If the degrees of freedom of the optimization without consideration of the inhomogeneity regions relate to the optimization of the entire region to be optimized, this may have a disproportionately negative effect on the overall result.

The inhomogeneous regions or inhomogeneity regions of the at least one magnetic field map may be included in a different manner, in particular weaker, in the optimization of the at least one pulse, e.g., at least one dynamic pulse, than more homogenous regions. This advantageously makes it possible to avoid the optimization of the inhomogeneity regions having too negative an effect on that of the more homogeneous regions.

The at least one magnetic field map may include at least one B1 field map (B1 map for short), and/or at least one B0 field map (B0 map for short).

The B1 field map may describe a spatial distribution of a B1 field. A B1 map may be a representation (e.g., a spatial representation) of a B1 field. The B1 field may be an alternating magnetic field (of the RF irradiation), which may be generated by a radiofrequency antenna unit of a magnetic resonance apparatus. The B0 field map may describe a spatial distribution of a B0 field. A B1 map may be a representation (e.g., a spatial representation), of a B0 field. The B0 field may be the static main magnetic field of the magnetic resonance apparatus. The B0 field may be generated by a main magnet, (e.g., a superconductive main magnet), of the magnetic resonance apparatus. A B1 field or a B0 field may be represented by an image in which the intensity of an image pixel or image voxel indicates the strength of the B1 field or of the B0 field at the location of the image pixel or image voxel.

Advantageously, the B1 and/or the B0 field describe the respective field distribution when the patient is located in an examination region of the magnetic resonance apparatus, in particular in a measurement position. In particular, in the case of higher magnetic field strengths, the presence of the patient may give rise to greater inhomogeneities of the fields. Such inhomogeneities may advantageously be reduced by the ascertained pulse, e.g., dynamic pulse.

The inhomogeneity region may relate to a region in the at least one magnetic field map in which the at least one homogeneity condition is not fulfilled. An individual inhomogeneity region may include a pixel and/or voxel or an, in particular contiguous, group of pixels and/or voxels of the at least one magnetic field map.

To generate the at least one magnetic field map, a magnetic resonance measurement may be carried out, (e.g., applied), with which the magnetic resonance signals are recorded, on the basis of which the at least one magnetic field map, in particular a B1 and/or B0 field map, may be generated. A range of methods for generating B1 and/or B0 field maps are known.

The homogeneity condition may include a maximum deviation, in particular maximum permitted deviation, of a magnetic field, in particular of a magnetic field strength, of the at least one magnetic field map from a target value. The target value may be a nominal value of a magnetic field strength. In the case of a B0 field map, the target value may be a nominal value of a strength of the main magnetic field of the magnetic resonance apparatus. Magnetic field strengths of main magnetic fields may be 1.5 T, 3 T, or 7 T. In the case of a B1 field map, the target value may be a nominal value of a transmit magnetic field. The maximum deviation of the magnetic field may be a maximum deviation of a B1 field and/or of a B0 field.

For example, a deviation of ±2500 Hz, in particular ±1000 Hz, in particular ±100 Hz, may be ascertained as the maximum deviation from the target value for the B0 field. For example, a deviation of ±10 ppm may be ascertained as the maximum deviation from the target value for the B0 field. For example, a deviation of ±50%, in particular ±20%, in particular ±5%, may be ascertained as the maximum deviation from the target value for the B1 field.

The provision of the at least one homogeneity condition may include providing at least one measurement boundary condition for the magnetic resonance measurement and ascertaining the at least one homogeneity condition based on the at least one measurement boundary condition. The at least one measurement boundary condition may be a boundary condition on which optimization possibilities, in particular degrees of freedom, for ascertaining the at least one pulse, e.g., at least one dynamic pulse, are dependent. In certain examples, the smaller the optimization possibilities resulting from the at least one measurement boundary condition, the more restrictive the at least one homogeneity condition when ascertaining the optimized at least one pulse, e.g., at least one dynamic pulse.

In particular, the smaller the optimization possibilities resulting from the at least one measurement boundary condition, the smaller the maximum deviation of a magnetic field, in particular of a magnetic field strength, of the at least one magnetic field map from a target value when ascertaining the optimized at least one pulse, e.g., at least one dynamic pulse.

Advantageously, the at least one homogeneity condition is less strict if the at least one measurement boundary condition permits a higher level of degrees of freedom for ascertaining the optimized at least one pulse, e.g., at least one dynamic pulse. Advantageously, the at least one pulse, (e.g., at least one dynamic pulse), may still be optimized successfully even in the case of a greater inhomogeneity of the magnetic field if the negative consequences of the greater inhomogeneity may be attenuated more effectively by a higher level of degrees of freedom.

During the ascertainment of the at least one pulse, (e.g., at least one dynamic pulse), possible degrees of freedom for the pulse calculation may be produced as a function of the at least one measurement boundary condition, wherein regions with particularly high deviations make use of particularly large optimization degrees of freedom of the pulse calculation. By ascertaining the at least one homogeneity condition on the basis of the at least one measurement boundary condition, it is advantageously possible to address the same in a targeted manner.

The measurement boundary condition may be in particular examination-specific, in particular patient-specific, and/or apparatus-specific.

An examination-specific measurement boundary condition may be a boundary condition that is specific to the magnetic resonance measurement for which the at least one pulse, (e.g., at least one dynamic pulse), is ascertained. It may depend on the patient to be examined with the magnetic resonance measurement.

The measurement boundary condition may include a maximum pulse duration and/or a minimum pulse duration and/or a measurement field of view (FOV), in particular a region to be optimized in the measurement field of view, and/or a body region to be measured.

An apparatus-specific measurement boundary condition may be a boundary condition that is specific to the magnetic resonance apparatus with which the magnetic resonance measurement is to be carried out.

The measurement boundary condition may include a maximum amplifier power, in particular RF amplifier power, and/or a maximum gradient strength, e.g., specified in the unit mT/m, and/or a maximum slew rate, e.g., specified in the unit T/m/s, and/or an available number of transmission channels. The maximum gradient strength and/or the maximum slew rate is predetermined in particular by a gradient coil unit of the magnetic resonance apparatus. The maximum amplifier power may include a maximum amplifier power of a radiofrequency power amplifier (RFPA) of the magnetic resonance apparatus at which a radiofrequency antenna unit of the magnetic resonance apparatus is operated. The available number of transmission channels may correspond to the number of transmission antennas of the radiofrequency antenna unit of the magnetic resonance apparatus.

The greater the maximum amplifier power and/or the maximum gradient strength and/or the maximum slew rate and/or the available number of transmission channels, the greater the degrees of freedom may be for ascertaining the optimized pulse, e.g., dynamic pulse. It is therefore also possible to determine more generous homogeneity conditions without this having too negative an effect overall on the optimization of the at least one pulse, e.g., at least one dynamic pulse. Advantageously, these degrees of freedom may be used more effectively as a result of considering the at least one homogeneity region.

For example, the consideration of the at least one inhomogeneity region when ascertaining the at least one pulse, (e.g., at least one dynamic pulse), includes an exclusion of the at least one inhomogeneity region, in particular of the pixels and/or voxels of the at least one inhomogeneity region, from the optimization of the at least one pulse, e.g., at least one dynamic pulse. In certain examples, the at least one inhomogeneity region is disregarded, in particular ignored, during the optimization of the at least one pulse, e.g., at least one dynamic pulse. For example, the pixels and/or voxels of the at least one inhomogeneity region may be left empty. Advantageously, an exclusion enables possible error sources or regions with high deviations to be ignored stringently.

For example, the consideration of the at least one inhomogeneity region when ascertaining the at least one pulse, e.g., at least one dynamic pulse, includes a modification of the at least one inhomogeneity region and an optimization of the at least one pulse, e.g., at least one dynamic pulse, on the basis of the modified at least one inhomogeneity region.

For example, the modification of the at least one inhomogeneity region includes replacing magnetic field values in the at least one inhomogeneity region with interpolated values. The interpolated values may be ascertained by interpolating the magnetic field values of the at least one magnetic field map adjacent to the at least one inhomogeneity region. As a result, it is advantageously possible to provide an adequate replacement for the original values of the at least one inhomogeneity region.

For example, the modification of the at least one inhomogeneity region includes replacing magnetic field values in the at least one inhomogeneity region with a predetermined reference value.

For example, the modification of the at least one inhomogeneity region includes replacing magnetic field values in the at least one inhomogeneity region with a value derived from the at least one homogeneity condition. In particular, this value may be a (maximum) deviation value, wherein if the deviation value is exceeded, the homogeneity condition is no longer fulfilled.

A magnetic resonance apparatus is also proposed, which is embodied to carry out a computer-implemented method as described above for ascertaining at least one pulse, (e.g., at least one dynamic pulse), of a magnetic resonance sequence for a magnetic resonance measurement. The magnetic resonance apparatus may include a computing unit, which may have one or several processors, and/or a memory unit, which may have one or several memory modules, in order to carry out the method.

Furthermore, a computer program product is proposed that includes a program and is configured to be directly loadable into a memory store of a programmable system control unit of a magnetic resonance apparatus, and includes program means, (e.g., libraries and auxiliary functions), in order to carry out a proposed method for ascertaining at least one pulse, e.g., at least one dynamic pulse, of a magnetic resonance sequence for a magnetic resonance measurement when the computer program product is executed in the system control unit of the magnetic resonance apparatus. In this context, the computer program product may include a piece of software with a source code, which still has to be compiled and linked or which only has to be interpreted, or an executable software code, which only has to be loaded into the system control unit for execution.

By way of the computer program product, the proposed method may advantageously be carried out in a rapid, identically repeatable, and robust manner. In certain examples, the computer program product is configured such that it may carry out the proposed method by the system control unit. In this context, the system control unit in each case has the prerequisites, such as a corresponding working memory, a corresponding graphics card or a corresponding logic unit for example, such that the respective method acts may be carried out efficiently.

The computer program product is saved on a (e.g., non-transitory) computer-readable medium or stored on a network or server, for example, from where it may be loaded into the processor of a local system control unit, which may be directly connected to the magnetic resonance apparatus or be part of the magnetic resonance apparatus. Furthermore, control information of the computer program product may be saved on an electronically readable data carrier. The control information of the electronically readable data carrier may be embodied in such a manner that it carries out a proposed method when the data carrier is used in a system control unit of a magnetic resonance apparatus.

Examples of electronically readable data carriers are a DVD, a magnetic tape, or a USB stick, on which electronically readable control information, in particular software, is saved. If this control information is read from the data carrier and saved into a system control unit of the magnetic resonance apparatus, it is possible to carry out all proposed embodiments of the method described above.

Further advantages, features, and details of the disclosure are provided in the exemplary embodiments described in the following, as well as on the basis of the drawings. Parts that correspond to one another are provided with the same reference characters in all figures.

### BRIEF DESCRIPTION OF THE DRAWINGS

FIG. 1 depicts an example of a magnetic resonance apparatus in a schematic representation.

FIG. 2 depicts an example of a method for ascertaining at least one pulse, (e.g., at least one dynamic pulse).

FIG. 3 depicts an example of a magnetic field map.

FIG. 4 depicts an example of a magnetic field map with two inhomogeneity regions.

### DETAILED DESCRIPTION

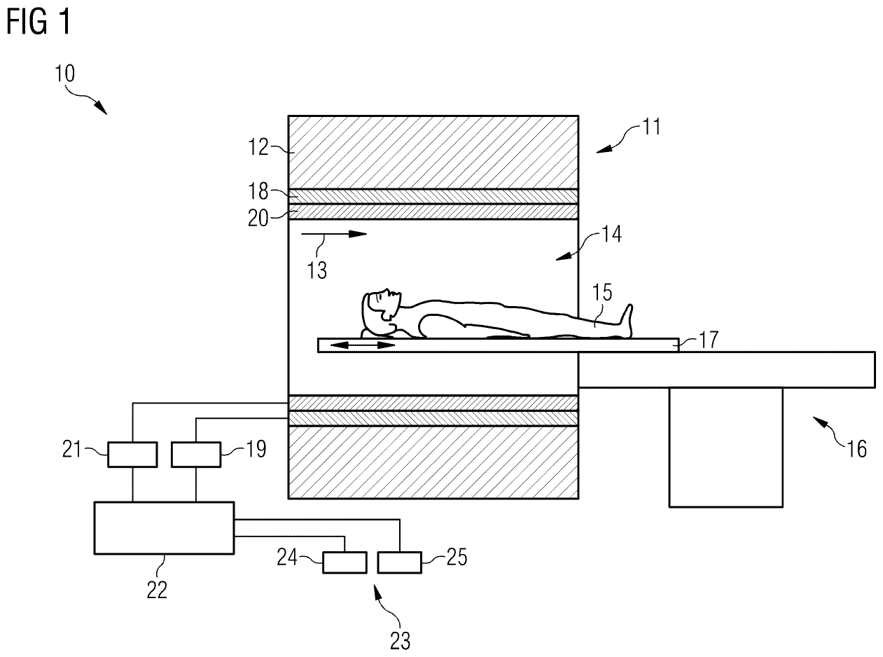

FIG. 1 is a schematic representation of a magnetic resonance apparatus 10. The magnetic resonance apparatus 10 includes a magnet unit 11, which has a main magnet 12 for generating a strong and, in particular, temporally constant main magnetic field 13 (B0 field). The magnetic resonance apparatus 10 also includes a patient placement region 14 for accommodating a patient 15. In the present embodiment, the patient placement region 14 is embodied as a cylinder and is enclosed in a circumferential direction cylindrically by the magnet unit 11. In principle, however, it is also conceivable that the patient placement region 14 has a different design. The patient 15 may be moved into the patient placement region 14 by a patient positioning apparatus 16 of the magnetic resonance apparatus 10. For this purpose, the patient positioning apparatus 16 has a patient table 17, which is configured to be movable within the patient placement region 14.

The magnet unit 11 also has a gradient coil unit 18 for generating magnetic field gradients that are used for spatial encoding during an imaging process. The gradient coil unit 18 is controlled by a gradient control unit 19 of the magnetic resonance apparatus 10. The magnet unit 11 furthermore includes a radiofrequency antenna unit 20, which in the present embodiment is embodied as a body coil permanently integrated into the magnetic resonance apparatus 10. The radiofrequency antenna unit 20 may have several transmission antennas so as to enable a parallel transmission technique (pTx). The radiofrequency antenna unit 20 is controlled by a radiofrequency antenna control unit 21 of the magnetic resonance apparatus 10 and, in order to generate a B1 field, irradiates RF pulses into an examination space formed by a patient placement region 14 of the magnetic resonance apparatus 10. As a result, an excitation of atomic nuclei ensues for the main magnetic field 13 generated by the main magnet 12. Magnetic resonance signals are generated due to relaxation of the excited atomic nuclei. The radiofrequency antenna unit 20 is also embodied to receive the magnetic resonance signals. It is also conceivable for the magnetic resonance apparatus to have a local coil for transmitting and/or receiving RF signals.

To control the main magnet 12, the gradient control unit 19 and to control the radiofrequency antenna control unit 21, the magnetic resonance apparatus 10 has a system control unit 22. The system control unit 22 controls the magnetic resonance apparatus 10 centrally, for example, the performance of a magnetic resonance sequence including at least one pulse, which is assumed in the following to be at least one dynamic pulse. In particular, the system control unit 22 may output a signal which is amplified by a radiofrequency power amplifier (not shown) and emitted by the radiofrequency antenna unit 20.

The system control unit 22 also includes an evaluation unit, not shown in further detail, for evaluating the magnetic resonance signals that are captured during the magnetic resonance examination. Furthermore, the magnetic resonance apparatus 10 includes a user interface 23, which is connected to the system control unit 22. Control information, such as imaging parameters, and reconstructed magnetic resonance images may be displayed on a display unit 24, (e.g., at least one monitor), of the user interface 23 for a member of medical operating personnel. Furthermore, the user interface 23 has an input unit 25 by which information and/or parameters may be input by the member of medical operating personnel during a measurement procedure.

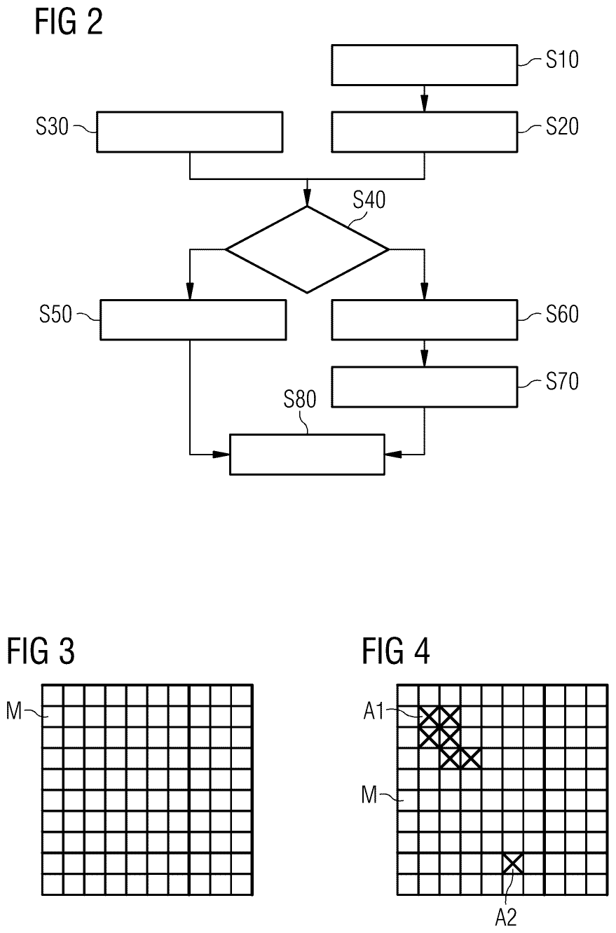

FIG. 2 shows an example of a method in which at least one dynamic pulse of a magnetic resonance sequence is ascertained for a magnetic resonance measurement.

In S10, at least one measurement boundary condition is provided. The measurement boundary conditions may include the following: permitted pulse duration of the dynamic pulse, available number of channels of the magnetic resonance apparatus 10, permitted or possible power of a radiofrequency power amplifier, usable gradient values of the gradient coil unit 18 (for example, maximum gradient strength and/or maximum slew rate), FOV or region to be optimized. In addition, the body region may play a role.

In S20, at least one homogeneity condition is ascertained on the basis of the at least one measurement boundary condition. The measurement boundary condition may be examination-specific, in particular patient-specific, and/or apparatus-specific. The measurement boundary conditions determine the parameter space and thus the degrees of freedom of the pulse calculation of the dynamic pulse, and thus the homogeneity condition. The homogeneity conditions may be expressed in the form of maximum deviation values, in particular threshold values. In the case of a magnetic resonance apparatus 10 with 8 transmission channels, for example, higher maximum deviation values are acceptable than on a magnetic resonance apparatus 10 with only one transmission channel. On the basis of an algorithm, the maximum deviation values for the magnetic field maps provided in S30, for example, B0 and/or B1 field map, therefore result. The maximum deviation values may lie in a range from ±100 Hz to ±2500 Hz for a B0 field map and ±5% to ±50% of the target value for a B1 field map.

In S40, the maximum deviation values are applied to the B0 and/or B1 field maps provided for optimization and pulse calculation in S30 in that a check is carried out to determine whether one or several inhomogeneity regions are present in the magnetic field maps in which the at least one homogeneity condition is not fulfilled.

If no inhomogeneity region is ascertained in S40, one or several dynamic pulses of a magnetic resonance sequence are ascertained accordingly in S50 without taking such a region into consideration.

If, on the other hand, a pixel or voxel of the magnetic field maps exceeds the maximum deviation values, there is an inhomogeneity region, which is taken into consideration in S70 when ascertaining at least one dynamic pulse of the magnetic resonance sequence which has been optimized on the basis of the at least one magnetic field map.

To this end, the magnetic field map is adapted in S60, which may take place in different variants, wherein the pixels or voxels of the inhomogeneity regions may be left empty (which means that these pixels or voxels are ignored during optimization of the at least one dynamic pulse), set to a reference value or the maximum deviation values, or interpolated via adjacent pixels or voxels. In certain examples, the variants mentioned first and last are used, as these either stringently ignore possible error sources or regions with high deviations (variant mentioned first) or provide an adequate replacement according to the local environment (variant mentioned last).

A possible adaptation of a magnetic field map in S60 is illustrated by way of example with reference to FIGS. 3 and 4.

FIG. 3 shows a magnetic field map M having 10×10 pixels, for example, a B1 or a B0 field map, which is provided in S30. A magnetic field strength value is assigned to each pixel. All pixels with a magnetic field strength value that deviates from a target value are part of an inhomogeneity region.

FIG. 4 shows a magnetic field map M with two inhomogeneity regions A1 (e.g., including six pixels) and A2 (e.g., including one pixel) by way of example. These, in particular masked-out, inhomogeneity regions are modified in S60 or taken into consideration in the pulse calculation in S70.

With the aid of the at least one magnetic field map that has been adapted in S60 (and therefore takes into consideration the at least one inhomogeneity region), the at least one dynamic pulse is then optimized or calculated in S70.

This pulse calculation advantageously involves less optimization effort to be expended in regions with extreme deviations, enabling an improved result to be achieved for the remaining regions.

If a fat saturation is to be achieved with the dynamic pulses, such inhomogeneity regions may be subject to artifacts in any case (for example on account of distortions and/or signal losses), such that they are for this reason already not particularly relevant for a diagnosis. Overall, the proposed method therefore enables the quality of dynamic pulses to be improved without a significant negative effect on the remaining image acquisition. Furthermore, it is advantageously possible (depending on the implementation of the method) to reduce the calculation duration of the dynamic pulses.

The dynamic pulses ascertained in S50 or S70 may then be used for a magnetic resonance measurement in S80.

Finally, it is again noted that the method described above in detail in the foregoing and the magnetic resonance apparatus shown are merely exemplary embodiments which may be modified by the person skilled in the art in a wide variety of ways without departing from the scope of the disclosure. Furthermore, the use of the indefinite article “a” or “an” does not preclude the possibility that the relevant features may also be present plurally. Similarly, the expression “unit” does not preclude the relevant components including a plurality of interacting subcomponents which may also be spatially distributed, if appropriate. Independent of the grammatical term usage, individuals with male, female or other gender identities are included within the term.

It is to be understood that the elements and features recited in the appended claims may be combined in different ways to produce new claims that likewise fall within the scope of the present disclosure. Thus, whereas the dependent claims appended below depend on only a single independent or dependent claim, it is to be understood that these dependent claims may, alternatively, be made to depend in the alternative from any preceding or following claim, whether independent or dependent, and that such new combinations are to be understood as forming a part of the present specification.

While the present disclosure has been described above by reference to various embodiments, it may be understood that many changes and modifications may be made to the described embodiments. It is therefore intended that the foregoing description be regarded as illustrative rather than limiting, and that it be understood that all equivalents and/or combinations of embodiments are intended to be included in this description.

1. A computer-implemented method for ascertaining at least one pulse of a magnetic resonance sequence for a magnetic resonance measurement, the method comprising:
providing at least one magnetic field map;
providing at least one homogeneity condition;
ascertaining at least one inhomogeneity region in the at least one magnetic field map in which the at least one homogeneity condition is not fulfilled; and
ascertaining the at least one pulse of the magnetic resonance sequence, which has been optimized based on the at least one magnetic field map, by taking into consideration the at least one inhomogeneity region.

2. The method of claim 1, wherein the at least one pulse comprises at least one dynamic pulse.

3. The method of claim 2, wherein the at least one dynamic pulse comprises at least one pTx pulse.

4. The method of claim 1, wherein the providing of the at least one homogeneity condition comprises providing at least one measurement boundary condition, having an influence on possibilities for optimizing the at least one pulse, for the magnetic resonance measurement, and
wherein the ascertaining of the at least one homogeneity condition is based on the at least one measurement boundary condition.

5. The method of claim 4, wherein the at least one measurement boundary condition is examination-specific, patient-specific, and/or apparatus-specific.

6. The method of claim 4, wherein the at least one measurement boundary condition comprises a maximum pulse duration, a minimum pulse duration, a measurement field of view, a body region to be measured by the magnetic resonance measurement, or a combination thereof.

7. The method of claim 6, wherein the measurement field of view is a region to be optimized in the measurement field of view.

8. The method of claim 4, wherein the at least one measurement boundary condition comprises a maximum amplifier power, a maximum gradient strength, a maximum slew rate, an available number of transmission channels, or a combination thereof.

9. The method of claim 1, wherein the at least one magnetic field map comprises at least one B1 field map and/or at least one B0 field map.

10. The method of claim 1, wherein the homogeneity condition comprises a maximum deviation of a magnetic field of a magnetic field strength of the at least one magnetic field map from a target value.

11. The method of claim 1, wherein the consideration of the at least one inhomogeneity region comprises an exclusion of the at least one inhomogeneity region from the optimization of the at least one pulse.

12. The method of claim 1, wherein the consideration of the at least one inhomogeneity region comprises a modification of the at least one inhomogeneity region and an optimization based on the modified at least one inhomogeneity region.

13. The method of claim 12, wherein the modification of the at least one inhomogeneity region comprises replacing magnetic field values in the at least one inhomogeneity region with interpolated values, and
wherein the interpolated values are ascertained by interpolating the magnetic field values of the at least one magnetic field map adjacent to the at least one inhomogeneity region.

14. The method of claim 12, wherein the modification of the at least one inhomogeneity region comprises replacing magnetic field values in the at least one inhomogeneity region with a predetermined reference value.

15. The method of claim 1, wherein the ascertaining of the pulse of the magnetic resonance sequence comprises optimizing a pulse form thereof based on the at least one magnetic field map.

16. The method of claim 1, wherein the pulse is a fat saturation pulse.

17. A magnetic resonance apparatus comprising:
at least one processor and at least one memory configured to:
provide at least one magnetic field map;
provide at least one homogeneity condition;
ascertain at least one inhomogeneity region in the at least one magnetic field map in which the at least one homogeneity condition is not fulfilled; and
ascertain at least one pulse of a magnetic resonance sequence, which has been optimized based on the at least one magnetic field map, by taking into consideration the at least one inhomogeneity region.

18. A non-transitory computer readable medium having a computer program product comprising a program configured to be loaded directly into a memory of a programmable system control unit of a magnetic resonance apparatus, wherein the program, when executed in the system control unit of a medical imaging apparatus, is configured to cause the medical imaging apparatus to:
provide at least one magnetic field map;
provide at least one homogeneity condition;
ascertain at least one inhomogeneity region in the at least one magnetic field map in which the at least one homogeneity condition is not fulfilled; and
ascertain the at least one pulse of a magnetic resonance sequence, which has been optimized based on the at least one magnetic field map, by taking into consideration the at least one inhomogeneity region.
